(19) United States
(12) Patent Application Publication
(10) Pub. No.: US 2007/0281659 A1
(43) Pub. Date: Dec. 6, 2007

(54) Multimedia device

(76) Inventor: Mike Chen, Jhanghe City (TW)

Correspondence Address: Troxell Law Office Pllc;Suite 1404, 5205 Leesburg Pike, Falls Church, VA, 22041, US

(21) Appl. No.: 11/445,318

(22) Filed: Jun. 2, 2006

(51) Int. Cl. H05K 11/02

(52) U.S. Cl. 455/345

(57) ABSTRACT

A multimedia device is composed of a machinery and a loose positioning seat. The machinery is provided with a control unit, a display unit, and a connection unit, and the control unit is electronically connected with the display unit and the connection unit, to provide for a selection of FM station to play, and for a connection to a digital music walkman. The loose positioning seat is assembled with the machinery. Accordingly, the machinery can be loosely assembled with all kinds of cup racks in a vehicle or similar structures in other locations by the loose positioning seat, such that the machinery can be easily and quickly assembled, can be firmly positioned, and can be carried and utilized conveniently.

### BACKGROUND OF THE INVENTION

(a) Field of the Invention

The present invention relates to a multimedia device, and more particular to a multimedia device which can be quickly and firmly positioned and assembled with all kinds of cup racks in a vehicle or with similar structures in other locations by assembling with a loose positioning seat, thereby being provided with effects of easy and quick to assemble, robust to position, and convenient to carry and utilize.

(b) Description of the Prior Art

A conventional multimedia device used in a vehicle is primarily composed of a transformation seat and a power cord, wherein the transformation seat can be used to connect with a digital music walkman (iPod) and the power cord is connected to a junction of cigarette-lighter, so as to provide a power source to the digital music walkman (iPod) or other electronic equipment through the transformation seat. Although the multimedia device is provided with an effect of supplying the power source to the digital music walkman (iPod) or other electronic equipment, the transformation seat does not have a positioning design; therefore, it will be usually fallen off due to a vibration of vehicle, upon using the multimedia device. Accordingly, in order to firmly position the transformation seat, a user will usually use a twin adhesive or a glue to directly fix the transformation seat. However, it will cause an inconvenience in replacing the seat and will stain the vehicle, if the seat needs to be removed or replaced; accordingly, it still not satisfies a requirement of the user in a real application.

### SUMMARY OF THE INVENTION

The primary object of present invention is to provide a multimedia device which can be quickly and firmly positioned and assembled with all kinds of cup racks in a vehicle or with similar structures in other locations by assembling with a loose positioning seat, thereby being provided with effects of easy and quick to assemble, robust to position, and convenient to carry and utilize, as well as greatly improving a practicability and convenience of the entire device.

Another object of the present invention is to provide a multimedia device which is installed with a control unit to be electronically connected with a display unit and a connection unit. In addition, the control unit is provided with a plurality of control keys to control an power on/off, select an FM (Frequency Modulation ) channel to play, and to quickly switch a channel, respectively; and the connection unit is provided with a connection seat, a connector, a power socket, and an audio socket, such that the multimedia device can be connected with a digital music walkman (iPod) and is provided with a charging function, thereby greatly improving a practicability and convenience of the entire device.

Still another object of the present invention is to provide a multimedia device wherein the connection seat can be replaced with a seat of different style by a design that the connection seat can be loosely assembled with the device, thereby increasing a choice of using the digital music walkman (iPod) and a practicability of the entire device. Accordingly, the multimedia device of present invention includes a machinery and a loose positioning seat, wherein the machinery is provided with a control unit, a display unit, and a connection unit. The control unit is electronically connected with the display unit and the connection unit to provide for tuning an FM station to play and for connecting with the digital music walkman, and the loose positioning seat is connected with the machinery. Accordingly, the machinery can be assembled with all kinds of cup racks in a vehicle or with similar structures in other locations by the loose positioning seat, thereby being provided with the effects of easy and quick to assemble, robust to position, and convenient to carry and utilize, as well as improving a practicability and convenience of the entire device.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view of an embodient of the present invention.

FIG. 2 shows an exploded view of an embodient of the present invention.

FIG. 3 shows an exploded view of a loose positioning seat of an embodient of the present invention.

FIG. 4 shows a cutaway view of a loose positioning seat, which is not yet collected, of an embodient of the present invention.

FIG. 5 shows a cutaway view of a loose positioning seat, which is collected, of an embodient of the present invention.

FIG. 6 shows a schematic view of a status of application of an embodient of the present invention.

### DETAILED DESCRIPTION OF THE PREFERRED EMBODIMENTS

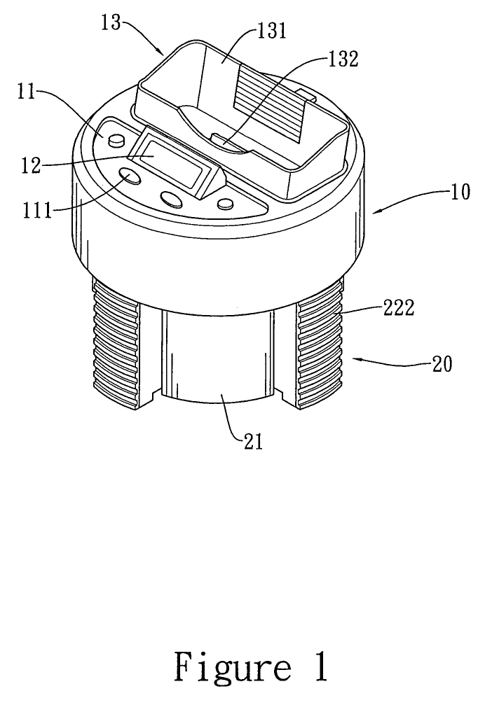

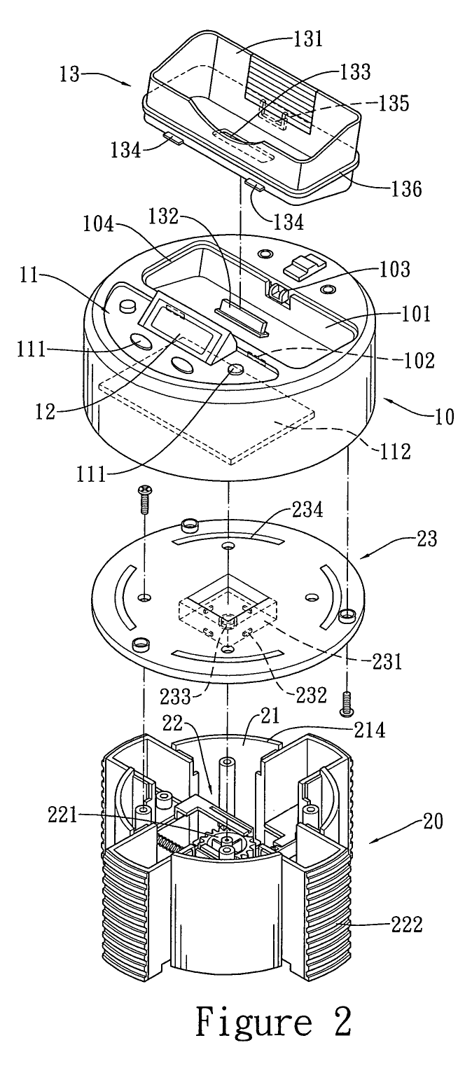

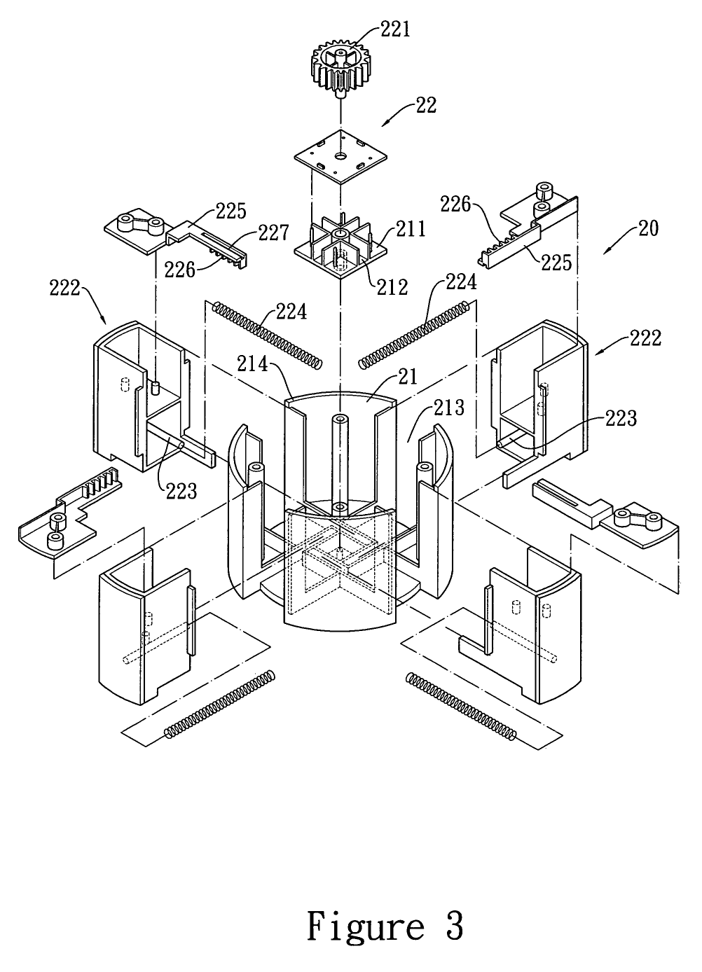

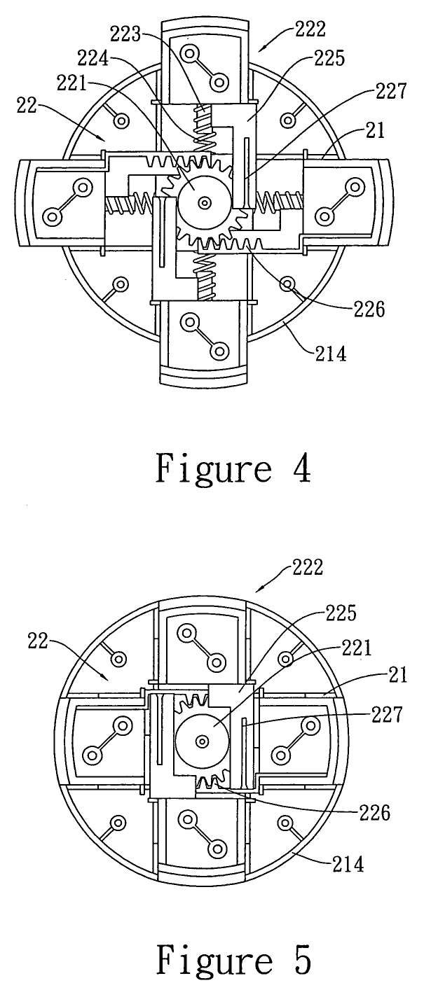

Referring to FIGS. 1 to 5, a machinery 10 is provided with a control unit 11, a display unit 12, and a connection unit 13, wherein the control unit 11 is electronically connected with the display unit 12 and the connection unit 13 to provide for tuning an FM station to play and for connecting to a digital music walkman (iPod), the control unit 11 includes a plurality of control keys 111 (such as a power on/off key, a channel tuning key, a channel switch key, etc.) and a control circuit 112, the display unit 12 is an LCD (Liquid Crystal Display) screen, and the connection unit 13 is provided with a connection seat 131 and a connector 132. A bottom of the connection seat 131 is provided with an opening 133 for providing a transfix of the connector 132, an end of the connection seat 131 is provided with at least one ridge 134, and the other end of connection seat 131 is provided with a concaved part 135. In addition, the machinery 10 is installed with a slot 101 corresponding to the connection seat 131 to provide for an emplacement of the connection seat 131. An end of the slot 101 is provided with a through-hole 102 to provide for a transfix of the corresponding ridge 134 of the connection seat 131, and the other end of slot 101 is provided with an elastic locking member 103 to be loosely positioned and assembled with the concaved part 135 at the other end of connection seat 131. An outer rim of the connection seat 131 is formed with an extension part 136, and an upper rim of the slot 101 is correspondingly formed with a grading part 104 to enable the connection seat 131 to be loosely positioned and assembled with the slot 101 of machinery 10.

A loose positioning seat 20 is assembled with the machinery 10 and comprises a seat body 21 and a driving positioning set 22. An interior of the seat body 21 is installed with a block 211, a periphery of the block 211 is partitioned into containing slots 212, and a periphery of the seat body 21 is formed with a plurality of opening slots 213. The driving positioning set 22 is loosely assembled with a gear 221 on the seat body 21, and the gear 221 is gnawed with a plurality of positioning members 222 (wherein, an inner side of the positioning member 222 is provided with an extension section 225 on which is installed with a teeth part 226 for enabling the gear 221 to be gnawed with the positioning member 222) below each of which is installed with a pillar 223 on which is sheathed with an elastic member 224, with one end of each elastic member 224 being transfixed into the containing slot 212 at the periphery of block 211 for enabling each positioning member 222 to be loosely positioned.

Moreover, the loose positioning seat 20 is also composed of a cover 23 which is assembled between the seat body 21 and the machinery 10. A bottom of the cover 23 is provided with a projection part 231 on which is installed with a projection piece 232, and the extension section 225 of the positioning member 222 is correspondingly provided with a guiding slot 227 for enabling the positioning member 222 to be loosely positioned and sliding. In addition, a center of the projection part 231 at the bottom of the cover 23 is installed with a sheath part 233, and the cover 23 is provided with a plurality of opening slots 234 which are corresponding to a plurality of ridges 214 installed on the seat body 21, so as to correspondingly sheath the plural opening slots 234 on the cover 23 with each ridge 214 on the seat body 21. On the other hand, the sheath part 233 of cover 23 is sheathed on an axis of the gear 221 on the seat body 21, so as to facilitate the cover 23 to be positioned and assembled with the seat body 21.

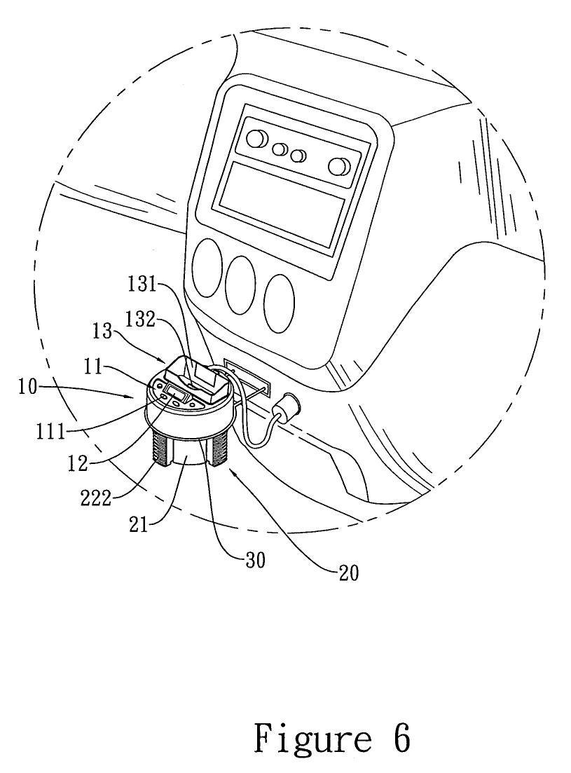

Referring to FIGS. 1 to 6, a multimedia device is constituted by the aforementioned structures. By a design which assembles the machinery 10 and the loose positioning seat 20, the machinery 10 can be quickly and firmly positioned and assembled with all kinds of cup racks 30 in a vehicle by the loose positioning seat 20. In addition, by a design which assembles the seat body 21, the driving positioning set 22, and the cover 23 of loose positioning seat 20, the loose positioning seat 20 can be formed into the design of perfect driving and robust positioning. Furthermore, by a control unit 11 which is installed on the machinery 10 and is electronically connected with the display unit 12 and the connection unit 13, by the plural control keys 111 (such as the power on/off key, the channel tuning key, the channel switching key, etc.) which are installed on the control unit 11 for controlling the power on/off of the machinery 10, selecting the FM station to play, and quickly switching the channel, respectively, and by the connection seat 131, the connector 132, a power socket, and an audio socket, which are installed on the connection unit 13, the machinery 10 can be connected to a digital music walkman (iPod) and is provided with a charging function. Moreover, by the slot 101 which is installed on the machinery 10 to correspond to the connection seat 131 for emplacing the connection seat 131, and by the design of connection seat 131 which can be loosely assembled with the machinery 10, a connection seat of different style can be replaced freely, thereby enabling the present invention to be provided with the effects of easy and quick to assemble, robust to position, and convenient to carry and use, as well as to be provided with an improvement of a practicability and convenience of the entire device.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A multimedia device including a machinery which is provided with a control unit, a display unit, and a connection unit, wherein the control unit is electronically connected with the display unit and the connection unit for providing for a selection of FM (Frequency Modulation) station to play, and for a connection to a digital music walkman; and a loose positioning seat which is assembled with the machinery, thereby loosely installing the machinery by the loose positioning seat.

2. The multimedia device according to claim 1, wherein the control unit is composed of a plurality of control keys and a control circuit.

3. The multimedia device according to claim 1, wherein the display unit is an LCD (Liquid Crystal Display) screen.

4. The multimedia device according to claim 1, wherein the connection unit is provided with a connection seat and a connector.

5. The multimedia device according to claim 4, wherein a bottom of the connection seat is provided with an opening for providing for a transfix of the connector, an end of the connection seat is provided with at least one ridge, the other end of the connection seat is provided with a concaved part, the machinery is provided with a slot corresponding to the connection seat for emplacing the connection seat, an end of the slot is provided with a through-hole for transfixing the ridge of connection seat, and the other end of slot is provided with an elastic locking member to be loosely positioned and assembled with the concaved part at the other end of connection seat.

6. The multimedia device according to claim 5, wherein an outer rim of the connection seat is formed with an extension part, and an upper rim of the slot is correspondingly formed with a grading part for enabling the connection seat to be loosely positioned and assembled with the slot of machinery.

7. The multimedia device according to claim 1, wherein the loose positioning seat includes a seat body and a driving positioning set; the seat body being provided with a block, and a periphery of which is partitioned into containing slots; a periphery of the seat body being formed with a plurality of opening slots; the driving positioning set being loosely assembled with a gear on the seat body with the gear being gnawed with a plurality of positioning members below each of which is provided with a pillar; each pillar being sheathed with an elastic member, and an end of each of which is transfixed into the containing slot partitioned at the periphery of block, for enabling each positioning member to be loosely positioned.

8. The multimedia device according to claim 7, wherein an inner side of the positioning member is formed with an extension section on which is provided with a teeth part, for enabling the gear to be gnawed with the positioning member.

9. The multimedia device according to claim 8, wherein the loose positioning seat is further provided with a cover which is assembled between the seat body and the machinery.

10. The multimedia device according to claim 9, wherein a bottom of the cover is provided with a projection part on which is installed with a projection piece, and the extension section of positioning member is correspondingly provided with a guiding slot, thereby enabling the positioning member to be loosely positioned and sliding.

11. The multimedia device according to claim 10, wherein a center of the projection part at the bottom of cover is provided with a sheath part, the cover is provided with the plurality of opening slots, and the seat body is provided with the ridges, so as to enable the plural opening slots on the cover to be sheathed with each ridge on the seat body; the sheath part of cover being sheathed on an axis of the gear of seat body, so as to facilitate the cover to be positioned and assembled with the seat body.
